(19) United States
(12) Patent Application Publication
(10) Pub. No.: US 2012/0170363 A1
(43) Pub. Date: Jul. 5, 2012

(54) METHOD FOR INCREASING PROGRAM SPEED AND CONTROL READ WINDOWS FOR MULTI-LEVEL CELL NON-VOLATILE MEMORY

(75) Inventors: Fu Kai Tsai, Banciao City (TW); Liu Chien Hung, Taipei City (TW)

(73) Assignee: Macronix International Co., Ltd.

(21) Appl. No.: 12/981,857

(22) Filed: Dec. 30, 2010

(51) Int. Cl. G11C 16/10

(52) U.S. Cl. 365/185.03

(57) ABSTRACT

A method of programming a memory device comprising a plurality of bits that each have a plurality of program states in which each program state has a corresponding program verify (PV) level may include applying a first sequence of program shots to program fastest bits of the memory device utilizing a bias voltage having a maximum value corresponding to a respective program state being programmed, lowering the bias voltage to apply a second sequence of program shots to program fast bits of the memory device up to N program shots, and increasing the bias voltage for program shots greater than N to program slow bits of the memory device.

### TECHNOLOGICAL FIELD

Embodiments of the present invention generally relate to programming of multi-level cell (MLC) memory devices and, more particularly, relate to a process for increasing programming speed and control read windows for MLC memory devices.

### BACKGROUND

Conventional flash memory cells store a charge on a floating gate that may be, for example, doped polysilicon. The stored charge changes a threshold voltage (Vt) of the memory cell. In a “read” operation, a read voltage is applied to the gate of the memory cell, and the corresponding indication of whether or not the memory cell turns on (e.g., conducts current) indicates the programming state of the memory cell. For example, a memory cell that conducts current during the “read” operation may be assigned a digital value of “1,” and a memory cell that does not conduct current during the “read” operation may be assigned a digital value of “0.” Charge may be added to and removed from the floating gate to program and erase the memory cell (e.g., to change the memory cell value from “1” to “0”).

Another type of memory uses a charge-trapping structure rather than the conductive gate material used in floating gate devices. The charge-trapping structure may have one or more cells each of which includes a charge-trapping layer and a non-conductive layer. When this type of structure is programmed, a charge may be trapped in the charge-trapping layer so that it does not move through the non-conductive layer. The charge may be retained by the charge-trapping layer until the memory cell is erased, thereby retaining the data state without requiring the application of a continuous source of electrical power. These charge-trapping cells can be operated as two-sided cells. In other words, because the charge does not move through the non-conductive charge trapping layer, charge can be localized on different charge-trapping sites. Thus, a so called multi-bit cell (MBC) may be created, which can increase the amount of data that can be stored in a memory device without consuming more space.

MBCs may have an erase-state Vt distribution at first and each bit of the memory may be thereafter programmed to a targeted programmed state. The Vt distribution of the targeted program state may have an associated program verify (PV) level (e.g., a lower boundary). In order to have a tightened Vt distribution of programmed bits, a pre-PV level for a targeted program state may be set lower than the PV level, and two steps of programming operations including a rough program operation and a fine program operation may be performed. However, the programming typically only focuses on the location of the lower boundary without paying attention to the upper boundary, and the upper boundary may affect the faster bits. Thus, it may be desirable to develop a process for increasing programming speed and control read windows for MLC memory devices to minimize adverse impacts on program distribution.

### BRIEF SUMMARY OF EXEMPLARY EMBODIMENTS

Embodiments of the present invention are therefore provided that may enable the provision of a method for programming a memory device (e.g., an MLC memory device) that is mindful of the location of the upper boundary. Accordingly, for example, read window margins may be controlled while program speed is increased. In some embodiments, slow bits may be programmed more quickly by increasing the bias voltage applied during programming of the slow bits to decrease the likelihood of over-programming the fastest bits, while still increasing the speed of programming the slow bits.

In an example embodiment, a method of programming a memory device is provided. The memory device may include a plurality of bits that each have a plurality of program states in which each program state has a corresponding program verify (PV) level. The method may include applying a first sequence of program shots to program fastest bits of the memory device utilizing a bias voltage having a maximum value corresponding to a respective program state being programmed, lowering the bias voltage to apply a second sequence of program shots to program fast bits of the memory device up to N program shots, and increasing the bias voltage for program shots greater than N to program slow bits of the memory device.

It is to be understood that the foregoing general description and the following detailed description are exemplary, and are not intended to limit the scope of the invention.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates a generic structure of a charge-trapping memory of a memory array according to an example embodiment of the present invention;

FIG. 2 illustrates the Vt window of each storage side of the charge-trapping memory of FIG. 1 according to an example embodiment of the present invention;

FIG. 3 shows an example two step program employing a rough program phase first, followed by a fine program phase;

FIG. 4 shows an example program sequence in which the locations of the high boundary are taken care of according to an example embodiment of the present invention;

FIG. 5 illustrates the program operation Vd bias (or BL bias) and program pulse shots for each programmed state in FIG. 2 according to an example embodiment of the present invention;

FIG. 6 illustrates an example process flow diagram for each programmed state shown in FIG. 2 for each side according to an example embodiment of the present invention; and

FIG. 7 is a block diagram describing a method for programming a memory device according to an example embodiment of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements. For example, references may be made herein to directions and orientations such as vertical, horizontal, diagonal, right, left, front, back, side or the like; it should be understood, however, that any direction and orientation references are simply examples and that any particular direction or orientation may depend on the particular object, and/or the orientation of the particular object, with which the direction or orientation reference is made.

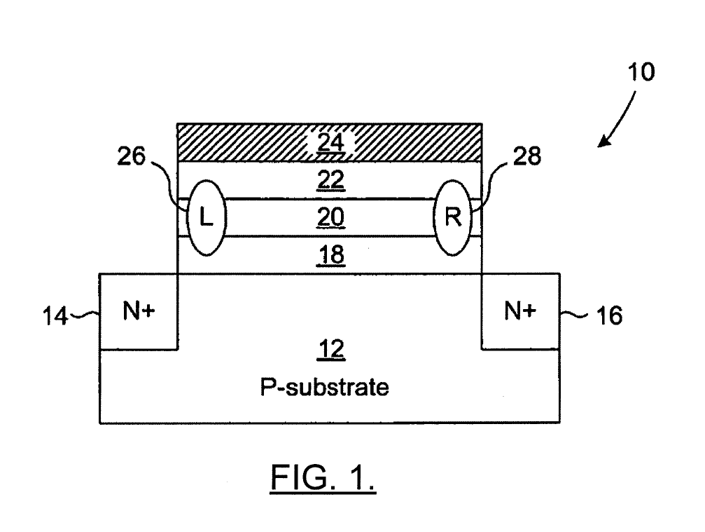

Some embodiments of the present invention may provide a process for increasing programming speed and control read windows for MLC memory devices to minimize adverse impacts on program distribution. FIG. 1 illustrates an example of a charge-trapping memory cell 10. As shown in FIG. 1, the charge-trapping memory cell 10 may include a gate 24 and symmetrical source/drain regions (e.g., S/D regions 14 and 16) that are in communication with a semiconductor channel or substrate 12. The substrate 12 and the gate 24 may be separated from a charge trapping layer 20 by insulation layers (e.g., oxide regions 18 and 22, respectively). In this example configuration, the left storage side 26 of the charge trapping layer 20 may be programmed and the right storage side 28 of the charge trapping layer 20 may be programmed.

The illustrated left storage side 26 and right storage side 28 may be programmed to one of four states (i.e., states 00, 01, 10 and 11) to thereby store two bits of data. Since accumulation of charge is an important feature of multi-bit programming, with more precise charge placement in the charge trapping layer 20, higher numbers of bits and states may be accurately achieved. A particular bit can be typically programmed, for example, by applying a potential to the gate 24 with one of the S/D regions 14 and 16 (e.g., region 16) acting as a drain and the other of the S/D regions 14 and 16 (e.g., region 14) acting as a source. The accumulation of charge at the particular side alters the threshold voltage of the left storage side 26 or right storage side 28. For example, to read the value 01 (also referred to as Level 1 for purposes of illustration), the applied potential may be between the right-most point of the Level 1 distribution and the left-most point of the Level 2 distribution. The region or window of values that the potential may have to comply with these criteria is called a “read window.”

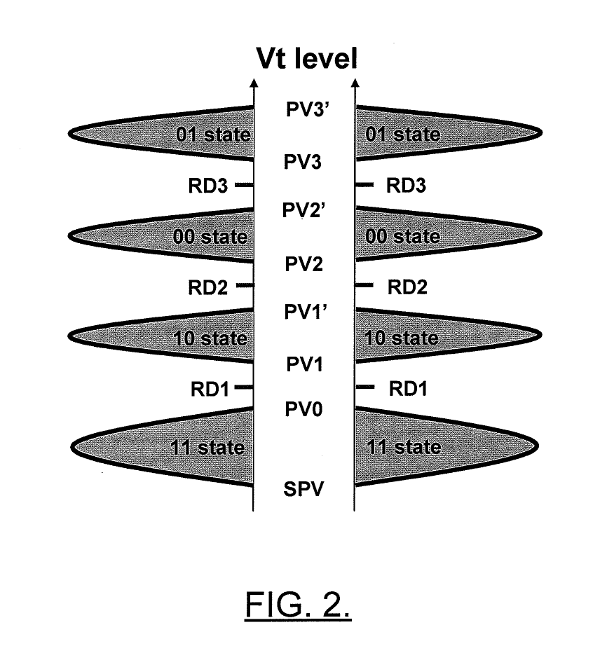

FIG. 2 illustrates the Vt window of each storage side according to an example embodiment. As is shown in FIG. 2, there are four states (01, 00, 10 and 11) at each side. Moreover, each state has a distribution including a lower boundary (PV) and an upper (or high) boundary (PV′). For reliable read operations, the read verify voltage (RD1, RD2, RD3) can be dynamically adjusted based on the upper and lower boundaries of distributions for the values 01, 00, 10 and 11.

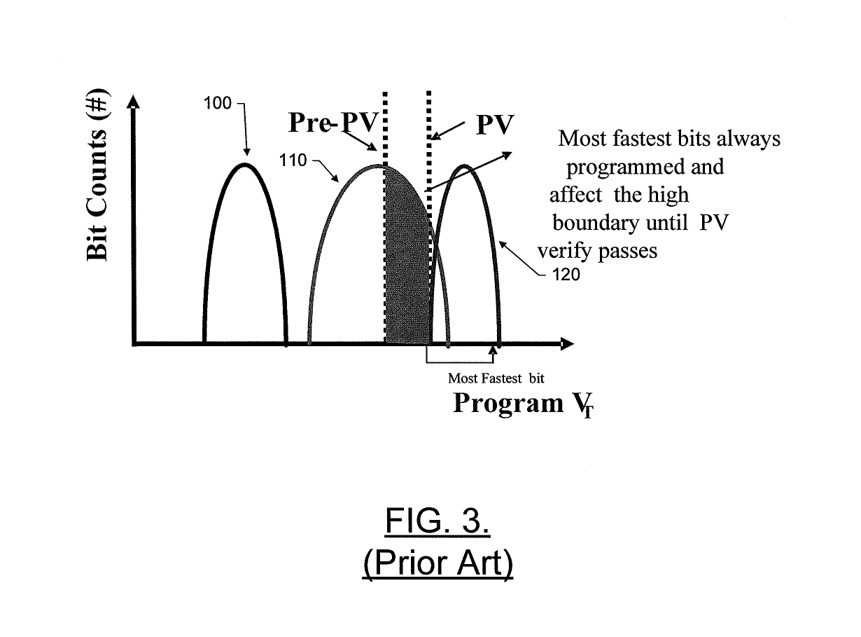

FIG. 3 shows an example two step program that first employs a rough program phase followed by a fine program phase. As shown in FIG. 3, in the rough program phase, bits are programmed to a Pre-PV level that is below the PV level by some offset. During the rough program phase, after a number of program shots, the bits of the memory are programmed to have a Vt distribution in which some bits have a Vt level at least as high as the Pre-PV level of the targeted program state, and other bits have a Vt level below the Pre-PV level. The memory may record the bits that pass, and those bits that do not pass may be further programmed using a fine program phase.

In the fine program phase, a finer bias may be applied to make sure that all bits pass the PV level in order to maintain a relatively tightened Vt distribution. In FIG. 3, distribution 100 represents the Vt distribution for the unprogrammed state, distribution 110 represents the Vt distribution after the rough program phase, and distribution 120 represents the Vt distribution after the fine program phase. As can be seen in FIG. 3, after the rough program phase, the fastest bits may be programmed and affect the high boundary until the PV level is passed. These fastest bits may also affect the program distribution due to their being programmed. Thus, according to this example, the location of the high boundary is not taken care of well and the tightened distribution relies on the fine program phase nearly entirely.

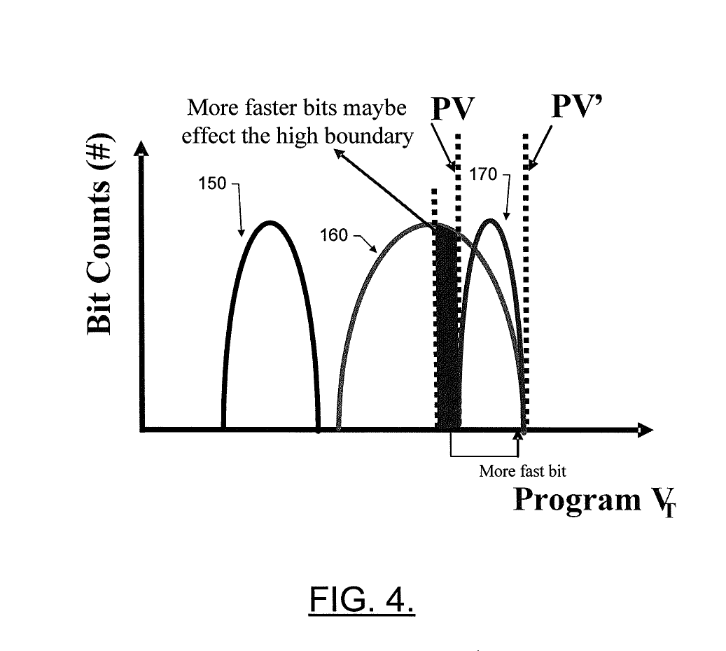

FIG. 4 shows an example program sequence in which the location of the high boundary is taken care of according to an example embodiment. As shown in FIG. 4, the high boundary (PV′) is the same after both rough programming and fine programming. In this regard, distribution 150 represents the Vt distribution for the unprogrammed state, distribution 160 represents the Vt distribution after the rough program phase, and distribution 170 represents the Vt distribution after the fine program phase. The Vt distribution 160 of FIG. 4 is further tightened relative to the Vt distribution 120 of FIG. 3.

During the rough program phase, the fastest bits may be programmed in just one or two shots due to those bits passing the PV′ level. During the fine program phase, programming may be performed with respect to only the bits of the memory that did not pass the PV level. Although the high boundary is taken care of, the high boundary may still be affected and the program speed may be somewhat slower during the fine program phase. If a high boundary shift occurs, the read window may be difficult to control. Thus, by dynamically adjusting the read verify level, example embodiments may achieve an increase in the reliable read ratio for an MLC memory.

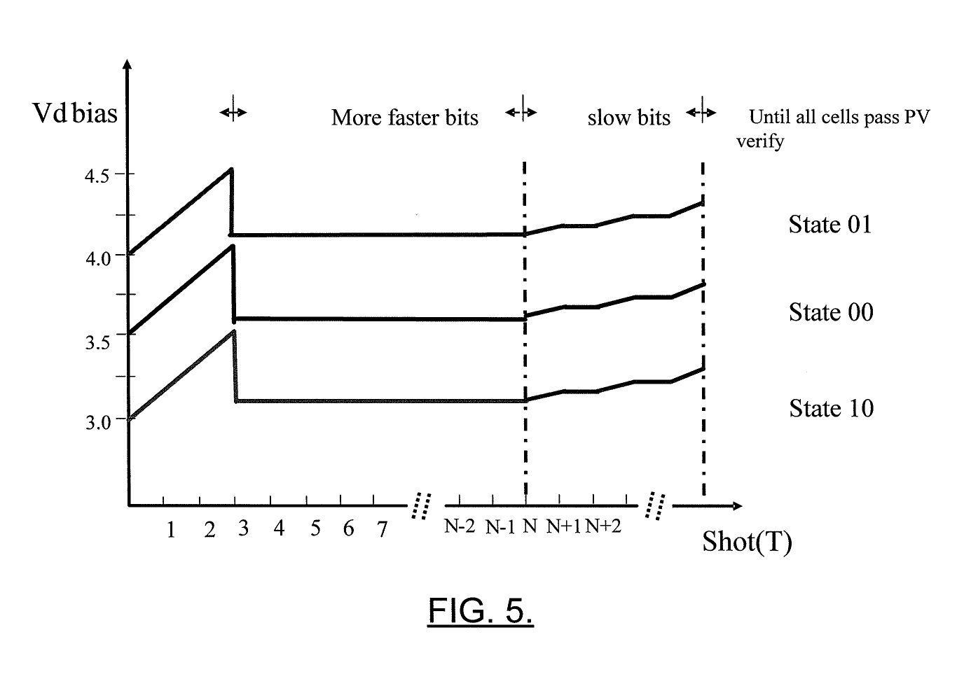

FIG. 5 illustrates the program operation Vd bias (or BL bias) and program pulse shots for each programmed state (e.g., 10, 00, and 01) in FIG. 2 for each side. As can be seen in FIG. 5, the fastest bits can be programmed to pass PV′ in one or two shots with successively increasing Vd bias being applied. While programming other faster bits, the Vd bias may decrease and may remain relatively level until N program shots have been performed, where N can be controlled by program speed. Meanwhile, the Vd bias voltage may remain at a relatively low level to reduce the probability of these faster bits affecting the high boundary. For the programming of slow bits, the applied, programming Vd bias voltage may be increased in order to increase speed. However, as shown in FIG. 5, the highest value of Vd applied during programming of slow bits may not exceed the highest value of Vd applied during programming of the fastest bits. By employing the process shown in FIG. 5, the possibility of over-programming faster bits that fail at previous program verify operations may be reduced and the program speed may be increased.

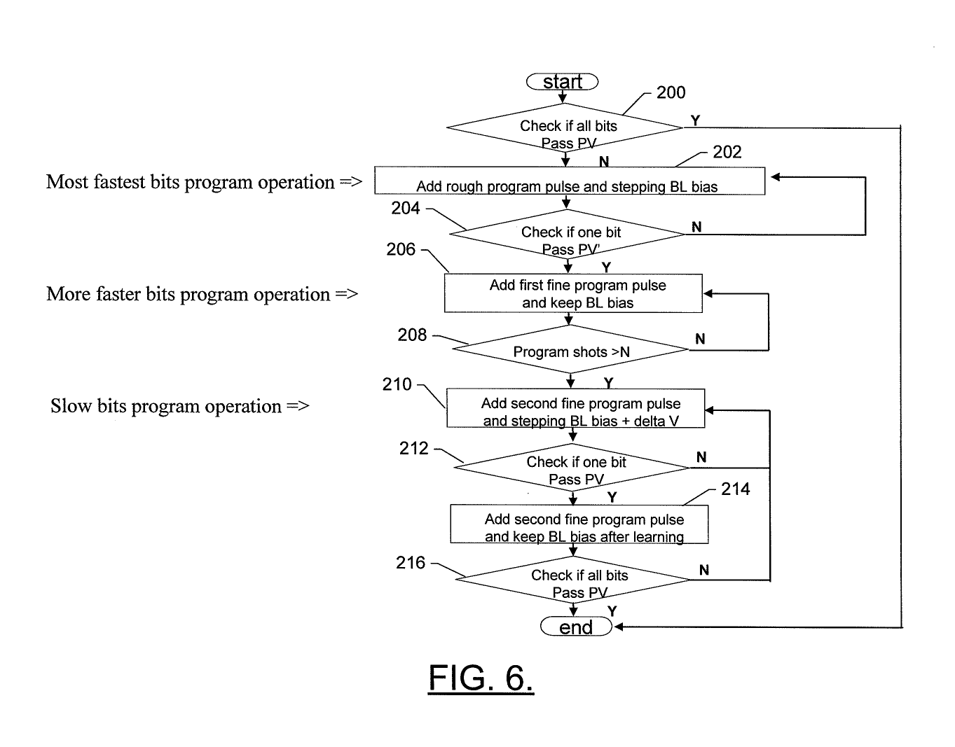

FIG. 6 illustrates an example process flow diagram for each programmed state (e.g., 10, 00 and 01) shown in FIG. 2 for each side. As shown in FIG. 6, all bits may initially be checked to see if they pass PV at operation 200, thereby employing a pre-program verification check to determine whether there are bits that need to be programmed. If all bits pass, then there is no need to conduct further programming. However, if some bits do not pass, the process may continue on to operation 202 where rough programming may be performed. At operation 202, a rough program pulse may be added to employ a rough Vd program profile (BL bias) until there is one bit that passes PV′ and the program shot number is limited to one or two shots. The check as to whether at least one bit passes PV′ may be accomplished at operation 204. The bit (or bits) programmed in this programmed bit group are the fastest bits. Selection of a rough Vd or Vg program profile may be accomplished in a manner that attempts to ensure that the at least one bit that passes is very near to the PV′ level.

After one bit passes PV′, at operation 206, a first fine Vd program pulse may be added, and a lower BL bias may be maintained, until the number of program pulse shots reaches the value N at operation 208. The program speed can be controlled by selection of the value of N pulse shots. During this period, other fast bits may be programmed. After programming the other fast bits, slower bits may be programmed by adding a second fine program pulse and stepping up or increasing the value of Vd (BL bias) at operation 210. A check may be made again to ensure that at least one bit passes PV at operation 212. If at least one bit has been programmed at operation 212, then the slow bit programming via the second fine program pulse addition may proceed at operation 214 by maintaining the BL bias until a check is passed at operation 216 to confirm that all bits pass PV. Meanwhile, if at least one bit has not been programmed at operation 212, the BL bias may be increased by cycling back through operation 210 until a bit is programmed and passes PV.

Some example embodiments may therefore control read window margins for flash devices and increase program speeds. The fastest bits may be programmed using one or two program shots until one bit passes PV′ and then BL bias may be decreased and maintained while programming other fast bits until N programming shots (N being selected to control program speed). By reducing the BL bias, the possibility of having faster bits effect the high boundary may be reduced. Thereafter, slow bit programming may be accomplished by increasing the BL bias, but while keeping the maximum BL bias below that which was used for programming the fastest bits. Accordingly, the likelihood of over-programming faster bits may be reduced and program speed may be increased.

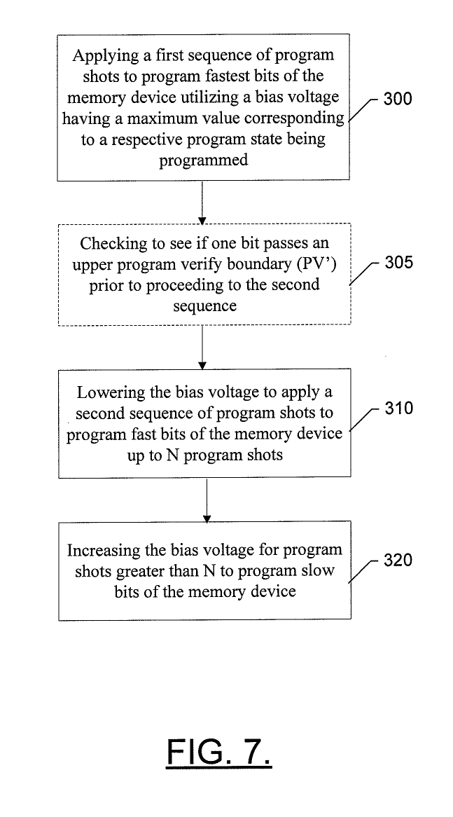

FIG. 7 is a flowchart illustrating operations associated with an example method of increasing programming speed and control read windows for MLC memory devices according to an example embodiment. It should be understood that each block of the flowchart, and combinations of blocks in the flowchart, can be implemented by various mechanisms, such as under the control of an operator or via hardware, firmware, and/or software including one or more computer program instructions. For example, one or more of the procedures described herein may be embodied by execution of computer program instructions (either with or without contribution from human operators). In this regard, the computer program instructions which embody the procedures described above may be stored by a memory and executed by a processor. As will be appreciated, any such computer program instructions may be loaded onto a computer or other programmable apparatus (i.e., hardware) to produce a machine, such that the instructions which execute on the computer or other programmable apparatus create means for implementing the functions specified in the flowchart block(s). These computer program instructions may also be stored in a computer-readable electronic storage memory that can direct a computer or other programmable apparatus to function in a particular manner, such that the instructions stored in the computer-readable memory produce an article of manufacture including instruction means which implement the function specified in the flowchart block(s). The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flowchart block(s).

Accordingly, blocks of the flowchart support combinations of means for performing the specified functions, combinations of operations for performing the specified functions and program instruction means for performing the specified functions. It will also be understood that one or more blocks of the flowchart, and combinations of blocks in the flowchart, can be implemented by special purpose hardware-based computer systems which perform the specified functions or operations, or combinations of special purpose hardware and computer instructions.

As shown in FIG. 7, a method for increasing programming speed and control read windows for MLC memory devices according to one example may include applying a first sequence of program shots to program fastest bits of the memory device utilizing a bias voltage having a maximum value corresponding to a respective program state being programmed at operation 300, lowering the bias voltage to apply a second sequence of program shots to program fast bits of the memory device up to N program shots at operation 310, and increasing the bias voltage for program shots greater than N to program slow bits of the memory device at operation 330.

In some embodiments, the operations above may be modified or amplified as described below. Moreover, in some cases, further operations may be conducted in addition to those discussed above, an example of which is shown in FIG. 7 in dashed lines. Some or all of the modifications, amplifications and/or additional operations may be combined in some embodiments in any order and in every possible combination. For example, in some cases, the method may further include checking to see if one bit passes an upper program verify boundary (PV′) at operation 305 prior to proceeding to the second sequence of operation 310. In some embodiments, increasing the bias voltage for program shots greater than N may include increasing the bias voltage by a first incremental amount and determining whether an additional bit passes PV. In an example embodiment, increasing the bias voltage for program shots greater than N may include maintaining the first incremental amount as long as the additional bit passes PV. In some embodiments, increasing the bias voltage for program shots greater than N may include increasing the bias voltage by a second incremental amount in response to no additional bit passing PV. In an example embodiment, increasing the bias voltage for program shots greater than N may include increasing the bias voltage until by respective incremental values, but maintaining the bias voltage below the maximum value corresponding to the respective program state being programmed. The value of N may be selected based on a desired program speed. The memory device may be a multi-level cell (MLC) memory device or a charge-trapping memory device. In some cases, applying the first sequence of program shots may include applying one or two program shots. In an example embodiment, applying the first sequence of program shots may include applying the bias voltage such that the bias voltage increases with each of the program shots applied in the first sequence of program shots up to the maximum value. In some embodiments, applying the first sequence of program shots may include employing a rough programming operation, lowering the bias voltage to apply the second sequence of program shots may include employing a first fine programming operation and increasing the bias voltage for program shots greater than N may include employing a second fine programming operation.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method of programming a memory device comprising a plurality of bits that each have a plurality of program states, each program state having a corresponding program verify (PV) level, the method comprising:
applying a first sequence of one or more program shots to program fastest bits of the memory device utilizing a bias voltage having a maximum value corresponding to a respective program state being programmed;
lowering the bias voltage to apply a second sequence of one or more program shots to program fast bits of the memory device up to N program shots; and
increasing the bias voltage for program shots greater than N to program slow bits of the memory device.

2. The method of claim 1, wherein increasing the bias voltage for program shots greater than N comprises increasing the bias voltage by a first incremental amount and determining whether an additional bit passes PV.

3. The method of claim 2, wherein increasing the bias voltage for program shots greater than N comprises maintaining the first incremental amount as long as the additional bit passes PV.

4. The method of claim 2, wherein increasing the bias voltage for program shots greater than N comprises increasing the bias voltage by a second incremental amount in response to no additional bit passing PV.

5. The method of claim 2, wherein increasing the bias voltage for program shots greater than N comprises increasing the bias voltage by respective incremental values, but maintaining the bias voltage below the maximum value corresponding to the respective program state being programmed.

6. The method of claim 1, wherein a value of N is selected based on a desired program speed.

7. The method of claim 1, wherein the memory device is a multi-level cell (MLC) memory device.

8. The method of claim 1, wherein the memory device is a charge-trapping memory device.

9. The method of claim 1, wherein applying the first sequence of program shots comprises applying only one or two program shots.

10. The method of claim 1, wherein applying the first sequence of program shots comprises applying the bias voltage such that the bias voltage increases with each of the program shots applied in the first sequence of program shots up to the maximum value.

11. The method of claim 1, further comprising checking to see if one bit passes an upper program verify boundary (PV′) prior to proceeding to the second sequence.

12. The method of claim 1, wherein applying the first sequence of program shots comprises employing a rough programming operation.

13. The method of claim 12, wherein lowering the bias voltage to apply the second sequence of program shots comprises employing a first fine programming operation.

14. The method of claim 13, wherein increasing the bias voltage for program shots greater than N comprises employing a second fine programming operation.
